(19) United States
(12) Patent Application Publication
(10) Pub. No.: US 2007/0113785 A1
(43) Pub. Date: May 24, 2007

(54) Radio frequency grounding apparatus

(75) Inventor: Chang Sung Ho, Jhongpu Township (TW)

Correspondence Address: John S. Egbert;Egbert Law Offices, 7th Floor, 412 Main Street, Houston, TX, 77002, US

(73) Assignee: CELETECH SEMICONDUCTOR, Inc., Jubei City (TW)

(21) Appl. No.: 11/390,927

(22) Filed: Mar. 28, 2006

(30) Foreign Application Priority Data
Nov. 23, 2005 (TW) 094220284

(51) Int. Cl. C23F 1/00; C23C 16/00

(52) U.S. Cl. 118/723 E; 156/345.47

(57) ABSTRACT

The radio frequency (RF) grounding apparatus of the present invention uses a clamp to clamp an RF grounding rod by surface contact to improve the connection stability. The clamp is connected to a flexible conductive sheet to form a grounding path to avoid the arcing generated by the bottom part (e.g., a heater) of a traditional plasma reaction chamber and to avoid breakage of the ceramic surface of the bottom part of the plasma reaction chamber, which would be caused by the RF grounding rod due to thermal expansion. The heater of the plasma reaction chamber, which is equipped with the RF grounding apparatus of the present invention, exhibits an extended lifetime. The top of the RF grounding rod is fixed to an RF mesh, and the RF grounding rod extends downward. The bottom of the RF grounding rod is clamped firmly and electrically by the clamp. The flexible conductive sheet connects the clamp and the grounding base of the plasma reaction chamber to form a grounding path.

### RELATED U.S. APPLICATIONS

Not applicable.

### STATEMENT REGARDING FEDERALLY SPONSORED RESEARCH OR DEVELOPMENT

Not applicable.

### REFERENCE TO MICROFICHE APPENDIX

Not applicable.

### FIELD OF THE INVENTION

The present invention relates to a radio frequency (RF) grounding apparatus, and more particularly to an RF grounding apparatus using a clamp and a flexible conductive sheet to form a grounding path, which is especially suitable for a plasma reaction chamber.

### BACKGROUND OF THE INVENTION

The deposition of dielectric material is one of the important steps in the semiconductor manufacturing process. Dielectric material is used as an intermetal dielectric (IMD) to isolate the adjacent metal lines electrically, as a passivation layer to protect the circuits on a chip from moisture and metal ions, and as a dielectric anti-reflection coating (DARC) in the lithography process. FIG. 1 illustrates a commonly used dielectric deposition system 1, which comprises a reaction chamber 11, an RF generator 18, an RF matching box 19 and an RF matching circuit 19′. The reaction chamber 11, which contains a heater 17 and an anode plate 14, is used to conduct the dielectric deposition process. The heater 17 is used to sustain and heat a wafer 16, which maintains a specific process temperature to conduct a process. The anode plate 14, an RF mesh 10 in the heater 17 and an RF grounding rod 13 form a conductive path to generate plasma 15. The RF generator 18, the RF matching box 19 and the RF matching circuit 19′ form an RF system to deliver the energy stably to the reaction chamber 11 to sustain the plasma 15 to conduct the dielectric deposition. The portion contacting the wafer 16 of the heater 17 is a ceramic surface (not shown). The RF mesh 10 is disposed under the ceramic surface and connected to the top of the RF grounding rod 13 whose bottom end is grounded. A resistive heater (not shown) inside the heater 17 is used to increase the temperature of the wafer 16 to the process temperature (in general, above 200°, which depends on different processes), to facilitate a dielectric film deposited on the surface of the wafer 16.

FIG. 2 illustrates a cross-section of the bottom of the heater 17 of FIG. 1, which shows the way to ground the RF grounding rod 13 in the prior art. Some prominent reeds 130, conductive electrically, are used to connect the bottom of the heater 17 and the bottom end of the RF grounding rod 13 by point contact. However, under a high-temperature environment for a long time, the prominent reeds 130 will decay and the spring force thereof applied to the bottom end of the RF grounding rod 13 will decrease. Therefore, the contact resistance between the bottom end of the RF grounding rod 13 and the prominent reeds 130 increases. Once the contact resistance increases, the RF energy passing through is apt to cause arcing, which results in high reflected power, unstable process conditions and oxidation of the bottom end of the RF grounding rod 13. The contact resistance deteriorated by the oxidation will increase the possibility of arcing. Accordingly, such a vicious cycle will seriously affect the yield rate of wafers and cause shutdown of the dielectric deposition system 1.

In the dielectric deposition process, the process temperature, in general, is above 200°, which expands the RF grounding rod 13 thermally and upward to press against the RF mesh 10 and then to break the ceramic surface above the RF mesh 10. Therefore, arcing is generated during the plasma-enhanced dielectric deposition process, which causes micro particles and results in micro-contamination and thus decreases the yield rate of wafers.

In addition, when the ceramic surface is broken, the whole heater 17 needs replacement, which shortens the lifetime of the heater 17 and decreases the up-time of the equipment (i.e., the dielectric deposition system). Consequently, the cost is increased. Therefore, it is necessary to improve the method of grounding the heater 17.

### BRIEF SUMMARY OF THE INVENTION

The objective of the present invention is to provide an RF grounding apparatus, and more particularly to an RF grounding apparatus using a clamp and a flexible conductive sheet to form a grounding path. The RF grounding apparatus utilizes the surface contact provided by the clamp and the flexible connection provided by the flexible conductive sheet to prevent arcing generated at a bottom part of a plasma reaction chamber (e.g., the heater of a plasma-enhanced chemical vapor deposition chamber). Additionally, the RF grounding apparatus of the present invention can avoid breakage of the ceramic surface that sustains a wafer, which would be caused by thermal expansion of the RF grounding rod. Thus, the lifetime of the bottom part of the plasma reaction chamber is extended.

In order to achieve the objective, the present invention discloses an RF grounding apparatus, which is applied to an RF grounding rod of a plasma reaction chamber. The RF grounding rod is installed in a bottom part of a plasma reaction chamber. The top of the RF grounding rod is fixed to an RF mesh and the RF grounding rod extends downward. The RF grounding apparatus comprises a clamp and a flexible conductive sheet. The clamp clamps the bottom of the RF grounding rod firmly and electrically. The flexible conductive sheet connects the clamp and a grounding base of the plasma reaction chamber to form a grounding path. When the RF grounding rod expands thermally and downward, the RF grounding rod moves in relation to the grounding base, i.e., a relative displacement is generated between the RF grounding rod and the grounding base, through the flexible connection provided by the flexible conductive sheet. Thus, the ceramic surface of the bottom part is prevented from breakage, which would be caused by thermal expansion of the RF grounding rod.

The RF grounding apparatus of the present invention can solve the issue of the decay of clamp force in prior arts, improve the grounding, extend the lifetime of the bottom part of the plasma reaction chamber, and further reduce the production cost.

### BRIEF DESCRIPTION OF THE SEVERAL VIEWS OF THE DRAWINGS

The invention will be described according to the appended drawings.

FIG. 1 is a schematic view illustrating a known dielectric deposition system.

FIG. 2 is a cross-sectional view illustrating a cross-section of the bottom of the heater shown in FIG. 1.

FIG. 3 is a perspective view illustrating an embodiment of the applications of the RF grounding apparatus of the present invention.

FIG. 4 is an exploded perspective view illustrating the RF grounding apparatus.

### DETAILED DESCRIPTION OF THE INVENTION

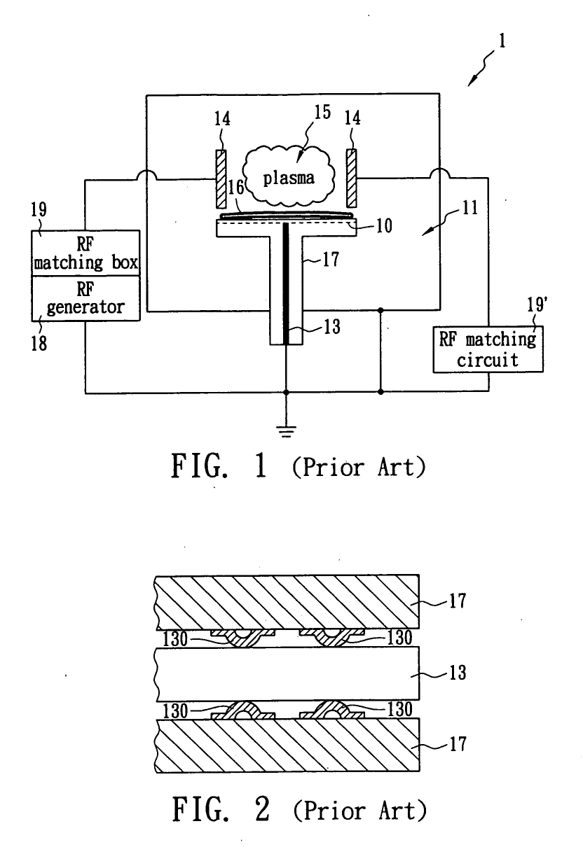

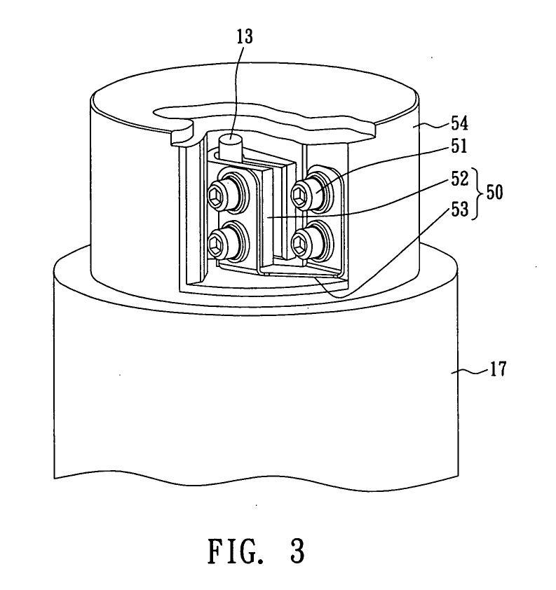

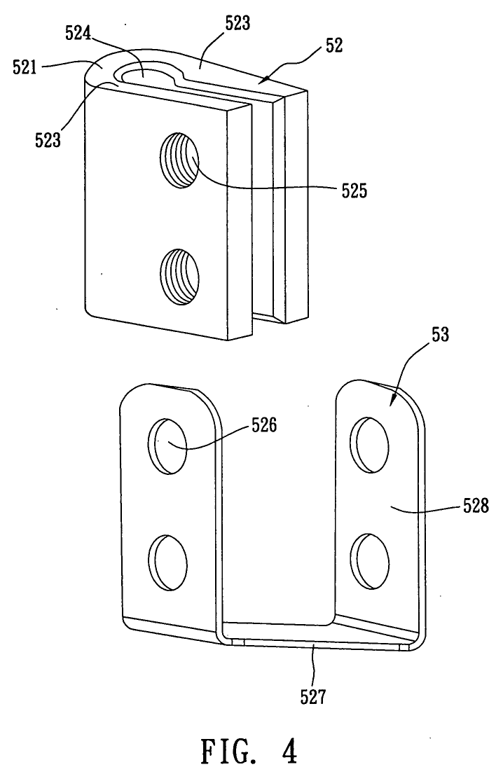

FIG. 3 shows one embodiment of the applications of the RF grounding apparatus of the present invention, which is upside-down for easy understanding. The RF grounding apparatus 50 is applied to an RF grounding rod 13 of a plasma reaction chamber. FIG. 4 shows an exploded view of the RF grounding apparatus 50. The RF grounding apparatus 50 comprises a clamp 52 and a flexible conductive sheet 53. The clamp 52 comprises two side portions 523 and an arced portion 524, which form a hollow portion to accommodate the bottom of the RF grounding rod 13. The flexible conductive sheet 53 is a U-like structure, which comprises two side plates 528 and a middle plate 527 connecting the two side plates 528. The thickness of the flexible conductive sheet, which is a metal sheet in the current embodiment, is from 0.1 mm to 5 mm. Each of the two side portions has a plurality of threaded holes 525 (two threaded holes in each side portion 523 in the current embodiment, and another two threaded holes are not shown due to the angle of view). Each threaded hole 525 corresponds to a through-hole 526 in the side plate 528. Thus, two fasteners 51 (two bolts in the current embodiment, refer to FIG. 3) can be used to fix one side plate 528 of the flexible conductive sheet 53 to the two side portions 523 of the clamp 52. Similarly, another side plate 528 can use another two bolts 51 through the through-holes 526 to fix itself to the grounding base 54 of the heater 17. The grounding base 54 is connected to a grounded terminal to form a grounding path (refer to FIG. 1). The space of the hollow portion 524 is compressed due to the two bolts 51 to clamp the bottom of the RF grounding rod 13 by surface contact.

The grounding path formed by the clamp 52 and the flexible conductive sheet 53 utilizes surface contact instead of point contact in the prior art. Therefore, a stable electrical connection between the grounding base 54 and the RF grounding rod 13 is maintained under high temperature and arcing is effectively eliminated. In addition, the flexible conductive sheet 53 cannot be too thick and should exhibit flexibility to allow the RF grounding rod 13 to move downward in relation to the grounding base 54 when the RF grounding rod 13 expands thermally due to high temperature. Accordingly, the RF grounding apparatus 50 can prevent the ceramic surface of the heater 17 from breakage, which would be caused by thermal expansion of the RF grounding rod 13.

In addition, a layer of conductive corrosion-resistant material (e.g., gold) can be coated on the surfaces of the RF grounding rod 13, the bolts 51, the clamp 52 and the flexible conductive sheet 53 to enhance the electrical conductivity, the property of anti-corrosion and lifetime thereof.

In the present invention, the connection between the flexible conductive sheet and the grounding base, and the connection between the clamp and the RF grounding rod, are not limited to the bolts and the threaded holes described in the embodiment. Other connection methods, which keep effective electrical connections, can be used, for example, bolts and a nut, and direct welding. Also, the RF grounding apparatus of the present invention can be applied in any reaction chamber of the semiconductor manufacturing process that is involved with plasma reaction, for example, a plasma-enhanced chemical vapor deposition chamber, a physical vapor deposition chamber, a plasma-enhanced etching chamber, and so on, to improve the grounding of the plasma reaction chamber.

The above-described embodiments of the present invention are intended to be illustrative only. Numerous alternative embodiments may be devised by persons skilled in the art without departing from the scope of the following claims.

I claim:

1. A radio frequency (RF) grounding apparatus, applied to an RF grounding rod of a plasma reaction chamber, said RF grounding apparatus comprising:
a clamp for clamping the RF grounding rod; and
a flexible conductive sheet connecting said clamp and a grounding base of the plasma reaction chamber to form a grounding path.

2. The RF grounding apparatus of claim 1, wherein the clamp clamps the RF grounding rod by surface contact.

3. The RF grounding apparatus of claim 1, wherein the RF grounding rod and the grounding base have a relative displacement therebetween.

4. The RF grounding apparatus of claim 3, wherein the relative displacement is caused by thermal expansion of the RF grounding rod.

5. The RF grounding apparatus of claim 1, wherein the flexible conductive sheet is connected to the clamp and the grounding base by a plurality of fasteners.

6. The RF grounding apparatus of claim 5, wherein the fasteners are comprised of bolts.

7. The RF grounding apparatus of claim 1, wherein the flexible conductive sheet is coated with a layer of conductive corrosive-resistant material.

8. The RF grounding apparatus of claim 1, wherein the RF grounding rod is installed in a heater of the plasma reaction chamber.

9. The RF grounding apparatus of claim 8, wherein the heater is used to carry a wafer in process.

10. The RF grounding apparatus of claim 1, wherein the plasma reaction chamber is used to conduct a chemical vapor deposition process.

11. The RF grounding apparatus of claim 1, wherein the clamp comprises two side portions and an arc portion forming a hollow portion accommodating a bottom of the RF grounding rod.

12. The RF grounding apparatus of claim 11, wherein each of the two side portions has a plurality of threaded holes to clamp the RF grounding rod.

13. The RF grounding apparatus of claim 1, wherein the flexible conductive sheet has a U-like shape and comprises two side plates and a middle plate connecting the two side plates.

14. The RF grounding apparatus of claim 13, wherein each of the two side plates has a plurality of through-holes to be fixed to the clamp and to the grounding base by bolts.

15. The RF grounding apparatus of claim 13, wherein the flexible conductive sheet is a metal sheet of a thickness between 0.1 mm and 5 mm.

16. The RF grounding apparatus of claim 7, wherein the layer of conductive corrosive-resistant material is comprised of gold.

17. The RF grounding apparatus of claim 1, wherein the plasma reaction chamber is used to conduct a physical vapor deposition process.

18. The RF grounding apparatus of claim 1, wherein the plasma reaction chamber is used to conduct an etching process.
